(19) United States
(12) Patent Application Publication
(10) Pub. No.: US 2025/0130110 A1
(43) Pub. Date: Apr. 24, 2025

(54) MICROBOLOMETER AND METHOD OF MANUFACTURING THE SAME

(71) Applicants: SAMSUNG ELECTRONICS CO., LTD., Suwon-si (KR); KOREA ADVANCED INSTITUTE OF SCIENCE AND TECHNOLOGY, Daejeon (KR)

(72) Inventors: Jae Chul PARK, Suwon-si (KR); Sanghun JEON, Seoul (KR)

(73) Assignees: SAMSUNG ELECTRONICS CO., LTD., Suwon-si (KR); KOREA ADVANCED INSTITUTE OF SCIENCE AND TECHNOLOGY, Daejeon (KR)

(21) Appl. No.: 18/745,212

(22) Filed: Jun. 17, 2024

(30) Foreign Application Priority Data
Oct. 24, 2023 (KR) 10-2023-0142588

(51) Int. Cl. G01J 5/20; H10N 15/10

(52) U.S. Cl. CPC G01J 5/20; H10N 15/10

(57) ABSTRACT

A microbolometer and a method of manufacturing the same are provided. The microbolometer may include a substrate, an absorption layer configured to absorb incoming light in a specific wavelength range and including an absorption body configured to float from the substrate and electrically isolated by a channel; a resistance layer provided between the substrate and the absorption body of the absorption layer and having a resistance value that changes based on temperature variations caused by thermal energy absorbed through the absorption layer; and a resistance reduction layer provided between the absorption layer and the resistance layer to reduce interface resistance and divided by a channel correspond to the channel of the absorption layer.

### CROSS-REFERENCE TO RELATED APPLICATION(S)

This application claims priority from Korean Patent Application No. 10-2023-0142588, filed on Oct. 24, 2023, in the Korean Intellectual Property Office, the disclosure of which is incorporated herein by reference in its entirety.

### BACKGROUND

### 1. Field

Apparatuses and methods consistent with example embodiments relate to a microbolometer that converts light energy coming from a specific wavelength band into heat energy and outputs it to generate image data.

### 2. Description of Related Art

An infrared sensor refers to a device that converts infrared signals radiated from an object into electrical signals for detection. Conventional visible image sensors have the disadvantage of difficulty in image acquisition when visible light is blocked, such as during nighttime operation or in the presence of smoke.

However, an infrared image sensor detects the amount of infrared radiation as an electrical signal based on the temperature and emissivity difference of an object, and converts the electrical signal into an image signal, thereby acquiring an image that is challenging for a visible light image sensor to detect.

Infrared has characteristics of both a wave and particles, like electrons. Infrared radiation in a specific range from an object collides with particles in the air or may be absorbed (atmospheric absorption notches).

By utilizing the property of the atmospheric window where the infrared radiation in the long-wave infrared (LWIR) range of 8-14 μm and the mid-wave infrared (MWIR) range of 3-5 μm passes through the atmosphere without causing absorption or collisions, infrared or thermal imaging sensors are manufactured. Particularly, objects at room temperature around 25° C. emit 50 times more radiant energy in the long-wave range than in the mid-wave range, thus radiation in the long-wave range is widely applied in the fields such as nighttime observation and thermal imaging.

Recently, microbolometers have been actively researched and have reached the stage of practical application. A microbolometer may be configured as a bolometer with a fine pixel, detecting a temperature change through a difference in electrical resistance of the bolometer changed by incident thermal radiation.

A non-cooled infrared detector with a microbolometer structure operates at room temperature, and thus does not need an extremely low-temperature cooling device and allows the CMOS process for pixel and ROIC fabrication on a silicon substrate to be performed simultaneously and monolithically.

To evaluate the performance of a non-cooled infrared detector, scales such as responsivity, indicating the change in output signal for incident infrared on the bolometer, noise caused by the uneven characteristics of an infrared detection layer, and detectivity of the bolometer due to responsivity and noise are considered.

For optimal performance of such detectors, the characteristics of the detection layer in the bolometer must be excellent. The detection layer used in the bolometer should not only have a high temperature coefficient of resistance (TCR) and low noise but also be stable as a material and well compatible with existing silicon processes.

Responsivity is closely related to TCR. As the TCR value of the bolometer increases, an input voltage signal also increases, showing a proportional tendency in responsivity. In the case of detectivity, it is inversely proportional to noise.

Noise equivalent temperature difference (NETD), unlike detectivity, is a factor that evaluates how well the detector can distinguish the temperature of external objects. Examining the definitions of responsivity, detectivity, and NETD, it can be understood that TCR and noise values are variables that have significant impact on core parameters of the bolometer.

However, since TCR and noise values are in a trade-off relationship, improving the performance of one variable tends to decrease the performance of the other. This is a fundamental issue with silicon thin films, and to address this, it is necessary to either change the material itself, or make structural changes while maintaining the properties of silicon.

### SUMMARY

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

According to an aspect of the present disclosure, a microbolometer may include: a substrate; an absorption layer configured to absorb incoming light in a specific wavelength range and comprising an absorption body configured to float from the substrate and electrically isolated by a channel; a resistance layer provided between the substrate and the absorption body of the absorption layer and having a resistance value that changes based on temperature variations caused by thermal energy absorbed through the absorption layer; and a resistance reduction layer provided between the absorption layer and the resistance layer to reduce interface resistance and divided by a channel correspond to the channel of the absorption layer.

The resistance reduction layer may be a high-concentration impurity layer with a doping concentration ranging from 10¹⁸ cm⁻³ to 10²⁰ cm⁻³.

The high-concentration impurity layer may be formed by depositing donor or acceptor impurities at a doping concentration ranging from 10¹⁸ cm⁻³ to 10²⁰ cm⁻³.

The high-concentration impurity layer may be formed by ion doping with donor or acceptor impurities at a doping concentration ranging from 10¹⁸ cm⁻³ to 10²⁰ cm⁻³.

The resistance reduction layer may include intermetallic compounds.

The channel in the absorption layer and the channel in the resistance reduction layer may be filled with a buffer layer.

The buffer layer may include silicon dioxide (SiO) or silicon nitride (SiN).

The absorption layer may include titanium nitride (TiN).

The resistance layer may include amorphous silicon or polycrystalline silicon.

The resistance layer and the absorption layer may be covered by an insulating film.

According to another aspect of the present disclosure, a method of manufacturing a microbolometer may include: operation (a) of forming a row electrode and a column electrode on a substrate, followed by sequentially laminating a sacrificial layer and a resistance layer; operation (b) of forming anchor holes penetrating from the resistance layer to the sacrificial layer to expose the row electrode and the column electrode, and forming a resistance reduction layer on the resistance layer; operation (c) of forming an absorption layer on the anchor holes and the resistance reduction layer; operation (d) of forming an electrically isolating channel penetrating through the absorption layer and the resistance reduction layer; and operation (e) of removing the sacrificial layer.

The operation (b) may include forming the anchor holes penetrating from the resistance reduction layer to the sacrificial layer after forming the resistance reduction layer by depositing donor or acceptor impurities at a doping concentration ranging from 10¹⁸ cm⁻³ to 10²⁰ cm⁻³ onto the resistance layer.

The operation (b) may include forming the anchor holes penetrating from the resistance reduction layer to the sacrificial layer after forming the resistance reduction layer by ion doping with donor or acceptor impurities at a doping concentration ranging from 10¹⁸ cm⁻³ to 10²⁰ cm⁻³ on the resistance layer.

The operation (b) may include depositing a metal material on the resistance layer and the anchor holes after forming the anchor holes penetrating from the resistance layer to the sacrificial layer, and forming the resistance reduction layer by removing a remaining metal material after forming intermetallic compounds on the metal material in contact with the resistance layer.

The operation (a) may include forming an insulating film between the sacrificial layer and the resistance layer.

According to an aspect of the present disclosure, a method of manufacturing a microbolometer may include: operation (a) of forming a row electrode and a column electrode on a substrate, followed by sequentially laminating a sacrificial layer and a resistance layer; operation (b) of patterning a buffer layer on the resistance layer; operation (c) of forming anchor holes penetrating from the resistance layer to the sacrificial layer to expose the row electrode and the column electrode, and forming a resistance reduction layer on the resistance layer such that the buffer layer is exposed to a set height; operation (d) of forming an absorption layer, which is divided by the buffer layer, on the anchor holes and the resistance reduction layer; and operation (e) of removing the sacrificial layer.

The operation (c) may include forming the anchor holes penetrating from the resistance reduction layer to the sacrificial layer after forming the resistance reduction layer by depositing donor or acceptor impurities at a doping concentration ranging from 10¹⁸ cm⁻³ to 10²⁰ cm⁻³ onto the resistance layer such that the buffer layer is exposed to the set height.

The operation (c) may include forming the anchor holes penetrating from the resistance reduction layer to the sacrificial layer after forming the resistance reduction layer by ion doping with donor or acceptor impurities at a doping concentration ranging from 10¹⁸ cm⁻³ to 10²⁰ cm⁻³ on the resistance layer such that the buffer layer is exposed to the set height.

The operation (c) may include depositing a metal material on the resistance layer, the buffer layer, and the anchor holes after forming the anchor holes penetrating from the resistance layer to the sacrificial layer, and forming the resistance reduction layer by removing a remaining metal material after forming intermetallic compounds on the metal material in contact with the resistance layer.

The operation (a) may further include forming an insulating film between the sacrificial layer and the resistance layer.

### BRIEF DESCRIPTION OF THE DRAWINGS

The above and/or other aspects will be more apparent by describing certain example embodiments, with reference to the accompanying drawings, in which:

FIG. 1 is a perspective view of a microbolometer according to embodiments of the present disclosure;

FIG. 2 is a plan view of the microbolometer shown in FIG. 1 according to embodiments of the present disclosure;

FIG. 3 is a cross-sectional view taken along line A-A of FIG. 2 according to embodiments of the present disclosure;

FIG. 4 is a cross-sectional view showing an example in which channels are filled with a buffer layer according to embodiments of the present disclosure;

FIG. 5 illustrates cross-sectional views for describing a method of manufacturing a microbolometer according to embodiments of the present disclosure;

FIG. 6 is a cross-sectional view for describing a method of forming a resistance reduction layer according to embodiments of the present disclosure;

FIG. 7 is a cross-sectional view for describing a method of forming a resistance reduction layer according to embodiments of the present disclosure;

FIG. 8 illustrates cross-sectional views for describing a method of manufacturing a microbolometer according to embodiments of the present disclosure;

FIG. 9 illustrates cross-sectional views for describing a method of forming a resistance reduction layer by adding a buffer layer according to embodiments of the present disclosure;

FIG. 10 illustrates cross-sectional views for a method of forming a resistance reduction layer by adding a buffer layer according to embodiments of the present disclosure; and

FIG. 11 is a diagram of an electronic device including a bolometer according to embodiments of the present disclosure.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

Terms such as first, second, and the like may be used to describe various elements, but the elements should not be limited to those terms. These terms may be used for the purpose of distinguishing one element from another element. The singular forms are intended to include the plural forms as well, unless the context clearly indicates otherwise.

It will be further understood that when an element is referred to as “comprising” or “including” another element, the element is intended not to exclude one or more other elements, but to further include one or more other elements, unless explicitly described to the contrary. The term used in the embodiments such as “unit” or “module” indicates a unit for processing at least one function or operation, and may be implemented in hardware, software, or in a combination of hardware and software.

Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples.

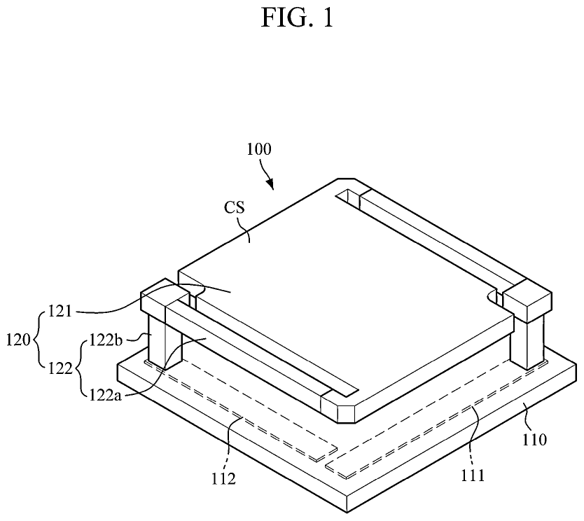

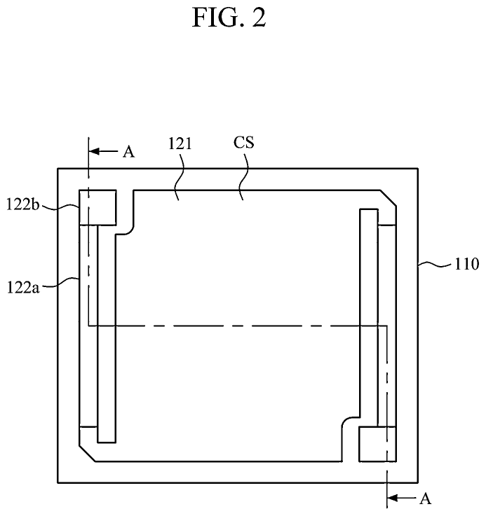

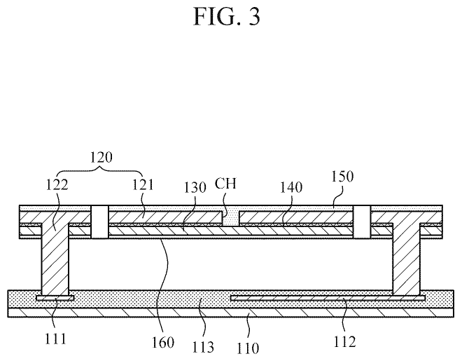

FIG. 1 is a perspective view of a microbolometer according to an embodiment. FIG. 2 is a plan view of the microbolometer shown in FIG. 1. FIG. 3 is a cross-sectional view taken along line A-A of FIG. 2.

Referring to FIGS. 1 to 3, according to one embodiment, a microbolometer 100 may include a substrate 110, an absorption layer 120, a resistance layer 130, and a resistance reduction layer 140.

Here, the microbolometer 100 may be configured as a bolometer with a fine pixel. The microbolometer 100 detects a temperature change through a difference in electrical resistance of the bolometer changed by incident thermal radiation.

On the substrate 110, a row electrode 111 and a column electrode 112 may be formed. The row electrode 111 and the column electrode 112 may be arranged in a strip form to be orthogonal to each other.

The row electrode 111 and the column electrode 112 may be covered by a protective layer 113. The protective layer 113, made of an insulating material such as silicon dioxide (SiO₂), protects and insulates the row electrode 111 and the column electrode 112. The substrate 110 may be made of a material such as silicon.

An infrared radiation reflective layer may be formed on the substrate 110.

The row electrode 111 and the column electrode 112 may be electrically connected to the resistance layer 130 through supports 122 of the absorption layer 120. By applying a bias voltage to the row electrode 111 and the column electrode 112, a read-out integrated circuit (ROIC) may detect current changes based on the change in resistance in the resistance layer.

The absorption layer 120 may absorb incoming light within a specific wavelength range. The absorption layer 120 may absorb infrared wavelengths. Light energy absorbed by the absorption layer 120 may be converted into thermal energy, raising the temperature of the resistance layer 130. The absorption layer 120 may be formed of a material such as titanium nitride (TiN) with a high thermal absorptivity.

The absorption layer 120 may have a central absorption body 121 supported by the supports 122 to float from the substrate 110. Each support 122 may include a supporting arm 122a and a leg 122b. The supporting arms 122a may extend from the diagonal corner portions of the central absorption body 121, spaced apart from both sides of the central absorption body 121. In the disclosure, the central absorption body 121 may be simply referred to as an absorption body.

The supporting arms 122a may have a constant width except for the region connected to the central absorption body 121, and they may be arranged at a regular distance from both sides of the central absorption body 121. The supporting arms 122a may be formed of the same material as the central absorption body 121. The supporting arms 122a may electrically connect the resistance layer 130 to the legs 122b.

The legs 122b may protrude from the row electrode 111 and the column electrode 112 and may be connected to extension ends of the supporting arms 122a to float the central absorption body 121 relative to the substrate 110. Like the supporting arms 122a, the legs 122b may be formed of the same material as the central absorption body 121. The legs 122b may be connected to the row electrode 111 and the column electrode 112 through the resistance layer 130.

The legs 122b may float a central detection area CS of the microbolometer 100, including the absorption layer 120 and the resistance layer 130, at a distance of a quarter of the incident wavelength 2 from the substrate 110.

The central absorption body 121 of the absorption layer 120 may be electrically isolated by a channel CH. The channel CH may be formed in the central absorption body 121 with a constant width and depth. Regions of the absorption layer 120 divided by the channel CH may be connected to the low electrode 111 and the column electrode 112, respectively.

Thus, the row electrode 111 and the column electrode 112 may be electrically isolated through the divided absorption layer 120 and connected to the resistance layer 130. The absorption layer 120 may be covered by an insulating film 150. The surface of the absorption layer 120 having the channel CH formed may be covered and protected by the insulating film 150. The insulating film 150 may be formed of a material such as silicon nitride (SiNₓ).

The distance between the resistance layer 130 and the substrate 110 is shorter than the distance between the central absorption body 121 of the absorption layer 120 and the substrate 110. In other words, the resistance layer 130 and the central absorption body 121 of the absorption layer 120 are positioned such that the substrate 110 is closer to the resistance layer 130 than to the central absorption body 121 of the absorption layer 120. The resistance value of the resistance layer 130 may change depending on the temperature variations caused by thermal energy absorbed through the absorption layer 120. The resistance layer 130 may be formed of amorphous silicon (a-Si) or polycrystalline silicon.

The resistance layer 130 may be formed on the supporting arms 122a. The resistance layer 130 may be covered by an insulating film 160. The insulating film 160 may cover and protect the surface of the resistance layer 130 close to the substrate 110.

The resistance reduction layer 140 is formed between the absorption layer 120 and the resistance layer 130 to reduce interface resistance. Various parameters may define the temperature coefficient of resistance (TCR), and may be primarily determined by defects within the resistance layer 130, such as a silicon thin film. A simple and effective method to reduce noise is to lower resistance among several ways to reduce noise.

The resistance reduction layer 140, without altering the properties of the resistance layer 130, reduces contact resistance between the absorption layer 120 and the resistance layer 130. Thus, the microbolometer 100 of this embodiment may enhance thermal resolution characteristics by improving noise reduction while maintaining the TCR value.

The resistance reduction layer 140 may be divided into regions by a channel CH formed to correspond to the channel CH formed in the absorption layer 120. The regions of the resistance reduction layer 140 divided by the channel CH may be connected to the low electrode 111 and the column electrode 112, respectively.

Therefore, the row electrode 111 and the column electrode 112 may be electrically isolated through the divided resistance reduction layer 140 and connected to the resistance layer 130. The channel CH of the resistance reduction layer 140 may be filled with the insulating film 150 that covers the absorption layer 120. The thinner the thickness of the resistance reduction layer 140, the lower the resistance, so the thickness may be set to 50 nm or less.

For example, the resistance reduction layer 140 may be a high-concentration impurity layer. The high-concentration impurity layer may be formed by depositing donor or acceptor impurities at a high concentration onto the resistance layer 130. The high-concentration impurity layer may be deposited as an n++ impurity layer on the resistance layer 130 using phosphorus or as a p++ impurity layer using boron. The concentration of the high-concentration impurity layer may be set between 10¹⁸ cm⁻³ and 10²⁰ cm⁻³.

Alternatively, the high-concentration impurity layer may be formed by ion doping with donor or acceptor impurities at a high concentration on the resistance layer 130. The high-concentration impurity layer may be doped as an n++ impurity layer on the resistance layer 130 using phosphorus or as a p++ impurity layer using boron.

In another example, the resistance reduction layer 140 may be formed of intermetallic compounds. The intermetallic compounds may be formed by depositing a metal material onto the resistance layer and then applying heat, causing the metal elements to diffuse into the resistance layer 130 and bond with atoms of the resistance layer 130. When the resistance layer 130 is made of silicon, the intermetallic compounds may form a silicide layer. The metal material for use may be nickel (Ni) or the like.

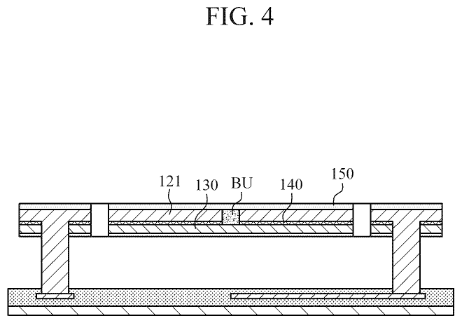

FIG. 4 is a cross-sectional view showing an example in which channels are filled with a buffer layer.

Referring to FIG. 4, as an additional aspect, channels may be filled with a buffer layer BU. When forming channels CH in the absorption layer 120 and the resistance reduction layer 140 through etching processes, the noise reduction characteristics may be compromised due to etching damage to the resistance layer 130.

To prevent degradation in noise reduction, instead of forming the channels CH in the absorption layer 120 and the resistance reduction layer 140 through etching processes, the buffer layer BU may be formed in the channel areas to electrically isolate the absorption layer 120 and the resistance reduction layer 140. The buffer layer BU may be formed of a material such as silicon dioxide (SiO) or silicon nitride (SiN).

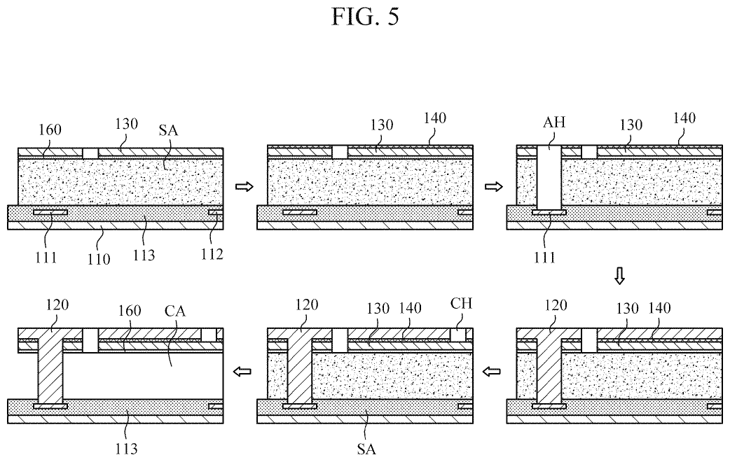

A method of manufacturing a microbolometer according to an embodiment will be described with reference to FIG. 5 as follows.

First, after forming a low electrode 111 and a column electrode 112 on a substrate 110, a sacrificial layer SA and a resistance layer 130 may be sequentially laminated. At this point, a protective layer 113 may be formed on the substrate 110 along with the row electrode 111 and column electrode 112 to protect and insulate the row electrode 111 and column electrode 112.

The substrate 110 may be made of a material such as silicon. The row electrode 111 and the column electrode 112 may be made of various conductive materials. The protective layer 113 may be made of an insulating material such as silicon dioxide. An infrared reflective layer may be formed on the substrate 110.

The sacrificial layer SA may be laminated on the protective layer 113 using a material such as amorphous carbon layer (ACL). The sacrificial layer SA is later removed through a subsequent etching process, creating a gap between the substrate 110 and supports 122 and forming a cavity between the substrate 110 and a central detection area CS of a microbolometer 100. The resistance layer 130 may be formed of amorphous silicon or polycrystalline silicon.

As an additional aspect, an insulating layer 160 may be formed between the sacrificial layer SA and the resistance layer 130. The insulating layer 160 may be formed of a material such as silicon nitride. The insulating film 160 and the resistance layer 130 may be patterned to expose the sacrificial layer SA in regions corresponding to the gap between the central detection area CS and supporting arms 122 of the microbolometer 100.

Next, anchor holes AH penetrating from the resistance layer 130 to the sacrificial layer SA, exposing the row electrode 111 and the column electrode 112 may be formed, and a resistance reduction layer 140 may be formed on the resistance layer 130.

At this time, the resistance reduction layer 140 may be formed by depositing donor or acceptor impurities at a high concentration onto the resistance layer 130. The resistance reduction layer 140 may be formed by depositing phosphorus onto the resistance layer 130 to form an n++ layer, or by depositing boron onto the resistance layer 130 to form a p++ layer.

The concentration of the resistance reduction layer 140 may be set between 10¹⁸ cm⁻³ and 10²⁰ cm⁻³. The thickness of the resistance reduction layer 140 may be set to 50 μm or less. The resistance reduction layer 140 may be patterned to correspond to the resistance layer 130. Subsequently, anchor holes AH penetrating from the resistance reduction layer 140 to the sacrificial layer SA may be formed.

Next, an absorption layer 120 may be formed on the anchor holes AH and the resistance reduction layer 140. In this case, the absorption layer 120 may be deposited on the anchor holes AH and the resistance reduction layer 140 with a material such as titanium nitride (TiN). The absorption layer 120 may be patterned to have a central absorption body 121 and supports 122. The absorption layer 120 formed on the anchor holes AH may constitute legs 122b.

Subsequently, an electrically isolating channel CH penetrating through the absorption layer 120 and the resistance reduction layer 140 may be formed. The electrically isolating channel CH may be formed by an etching process or the like on the absorption layer 120 and the resistance reduction layer 140. The absorption layer 120 and the resistance reduction layer 140 may have regions divided by the electrically isolating channel CH, which may be connected to the row electrode 111 and column electrode 112, respectively.

Then, an insulating film 150 (see FIG. 3) may be formed on the absorption layer 120 with a material such as silicon nitride (SiNₓ). The electrically isolating channel CH may be filled with the insulating film 150 for protection.

Subsequently, the sacrificial layer SA may be removed. The sacrificial layer SA may be removed through an etching process. Upon the removal of the sacrificial layer SA, a cavity CA may be formed between the insulating film 160 and the protective layer 113. Accordingly, as shown in FIG. 1, the central detection area CS of the microbolometer 100 may be floated from the substrate 110 by means of the supports 122.

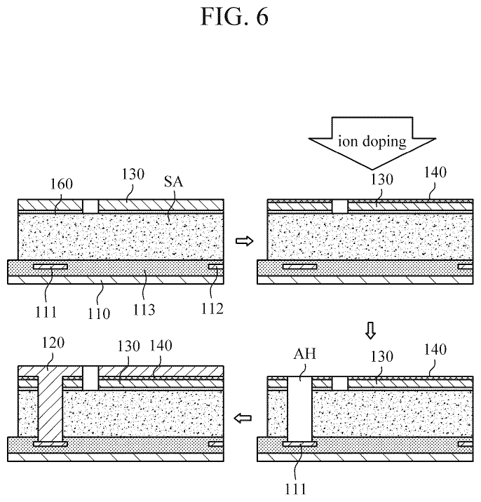

FIG. 6 is a cross-sectional view for describing another example of forming a resistance reduction layer.

First, after forming a low electrode 111 and a column electrode 112 on a substrate 110, a sacrificial layer SA and a resistance layer 130 may be sequentially laminated. In addition, as an additional aspect, an insulating layer 160 may be formed between the sacrificial layer SA and the resistance layer 130. These processes may be performed similarly to the example described above.

Next, the resistance reduction layer 140 may be formed by ion doping with donor or acceptor impurities at a high concentration on the resistance layer 130. The resistance reduction layer 140 may be formed by doping phosphorus on the resistance layer 130 to form an n++ layer, or by doping boron on the resistance layer 130 to form a p++ layer. The concentration of the resistance reduction layer 140 may be set between 10¹⁸ cm⁻³ and 10²⁰ cm⁻³. The thickness of the resistance reduction layer 140 may be set to 50 μm or less. The resistance reduction layer 140 may be patterned to correspond to or align with the resistance layer 130.

Subsequently, similarly to the example described above, anchor holes AH penetrating from the resistance reduction layer 140 to the sacrificial layer SA may be formed. The anchor holes AH may expose the row electrode 111 and the column electrode 112. Next, an absorption layer 120 may be formed on the anchor holes AH and the resistance reduction layer 140.

Subsequently, after forming an electrically isolating channel CH penetrating through the absorption layer 120 and the resistance reduction layer 140, the sacrificial layer SA may be removed. These processes may be performed similarly to the example described above.

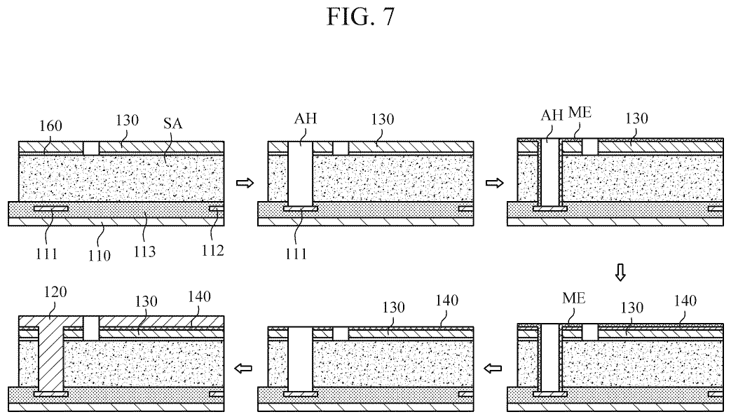

FIG. 7 is a cross-sectional view for describing still another example of forming a resistance reduction layer.

First, after forming a low electrode 111 and a column electrode 112 on a substrate 110, a sacrificial layer SA and a resistance layer 130 may be sequentially laminated. In addition, as an additional aspect, an insulating layer 160 may be formed between the sacrificial layer SA and the resistance layer 130. These processes may be performed similarly to the example described above.

Subsequently, anchor holes AH penetrating from the resistance layer 130 to the sacrificial layer SA may be formed. The anchor holes AH may expose the row electrode 111 and the column electrode 112.

Then, a metal material ME may be deposited on the resistance layer 130 and the anchor holes AH. The metal material ME may include nickel (Ni) or the like.

Next, intermetallic compounds may be formed on the metal material ME in contact with the resistance layer 130. In this case, the intermetallic compounds may be formed by applying heat to the resistance layer 130 on which the metal material ME is deposited, causing the metal elements to diffuse into the resistance layer 130 and bond with the atoms of the resistance layer. When the resistance layer 130 is made of silicon, the intermetallic compounds may form a silicide layer.

Then, the remaining metal material ME may be removed to form a resistance reduction layer 140. Next, an absorption layer 120 may be formed on the anchor holes AH and the resistance reduction layer 140. Subsequently, similarly to the example described above, after forming an electrically isolating channel CH penetrating through the absorption layer 120 and the resistance reduction layer 140, the sacrificial layer SA may be removed.

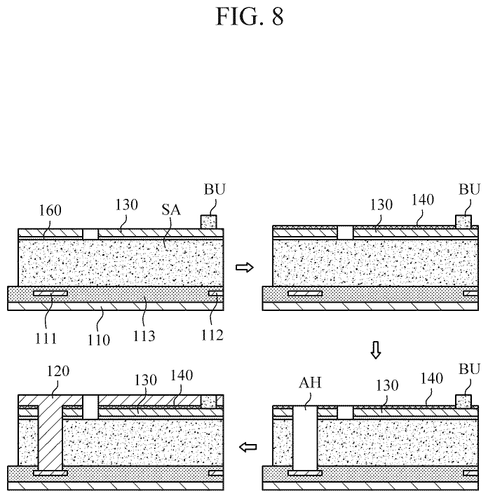

A method of manufacturing a microbolometer according to another embodiment will be described with reference to FIG. 8 as follows.

First, after forming a low electrode 111 and a column electrode 112 on a substrate 110, a sacrificial layer SA and a resistance layer 130 may be sequentially laminated. In addition, as an additional aspect, an insulating layer 160 may be formed between the sacrificial layer SA and the resistance layer 130. These processes may be performed similarly to the example described above.

Next, a buffer layer BU may be patterned on the resistance layer 130. In this case, the buffer layer BU may be formed to cross and divide the upper region of the resistance layer 130. The buffer layer BU may be formed with a specific width and height. The buffer layer BU may be formed of a material such as silicon dioxide (SiO) or silicon nitride (SiN).

Then, anchor holes AH penetrating from the resistance reduction layer 140 to the sacrificial layer SA may be formed, exposing the row electrode 111 and the column electrode 112. A resistance reduction layer 140 may be formed on the resistance layer 130 so that the buffer layer BU is exposed to a set height.

The resistance reduction layer 140 may be formed by depositing donor or acceptor impurities at a high concentration onto the resistance layer 130 such that the buffer layer BU is exposed to a set height. Similarly to the example described above, the resistance reduction layer 140 may be formed by depositing phosphorus onto the resistance layer 130 to form an n++ layer, or by depositing boron onto the resistance layer 130 to form a p++ layer. Subsequently, anchor holes AH penetrating from the resistance reduction layer 140 to the sacrificial layer SA may be formed.

Next, an absorption layer 120 divided by the buffer layer BU may be formed on the anchor holes AH and the resistance reduction layer 140. The absorption layer 120 may be deposited on the anchor holes AH and the resistance reduction layer 140 with a material such as titanium nitride (TiN) and then patterned. The absorption layer 120 may be patterned to have a central absorption body 121 and supports 122. An insulating film 150 (see FIG. 3) may be formed on the absorption layer 120 with a material such as silicon nitride (SiNₓ). Subsequently, the sacrificial layer SA may be removed.

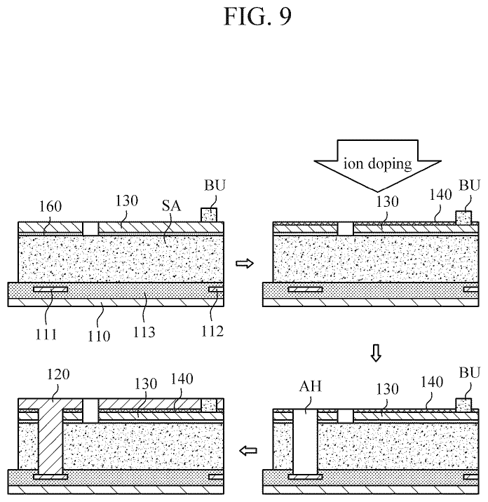

FIG. 9 illustrates cross-sectional views for describing an example of forming a resistance reduction layer by adding a buffer layer.

First, after forming a low electrode 111 and a column electrode 112 on a substrate 110, a sacrificial layer SA and a resistance layer 130 may be sequentially laminated. In addition, as an additional aspect, an insulating layer 160 may be formed between the sacrificial layer SA and the resistance layer 130. Next, a buffer layer BU may be patterned on the resistance layer 130. These processes may be performed similarly to the example described above.

Then, a resistance reduction layer 140 may be formed by depositing donor or acceptor impurities at a high concentration onto the resistance layer 130 such that the buffer layer BU is exposed to a set height. The resistance reduction layer 140 may be formed by doping phosphorus on the resistance layer 130 to form an n++ layer, or by doping boron on the resistance layer 130 to form a p++ layer. Subsequently, similarly to the example described above, anchor holes AH penetrating from the resistance reduction layer 140 to the sacrificial layer SA may be formed.

Next, an absorption layer 120 divided by the buffer layer BU may be formed on the anchor holes AH and the resistance reduction layer 140. Then, the sacrificial layer may be removed. These processes may be performed similarly to the example described above.

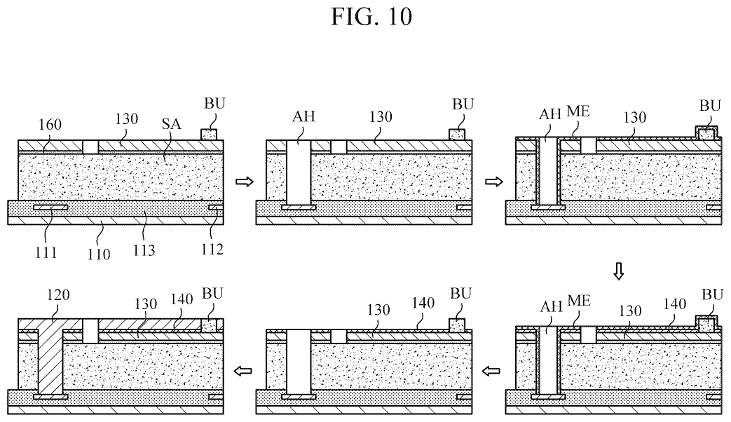

FIG. 10 illustrates cross-sectional views for describing another example of forming a resistance reduction layer by adding a buffer layer.

First, after forming a low electrode 111 and a column electrode 112 on a substrate 110, a sacrificial layer SA and a resistance layer 130 may be sequentially laminated. In addition, as an additional aspect, an insulating layer 160 may be formed between the sacrificial layer SA and the resistance layer 130. Next, a buffer layer BU may be patterned on the resistance layer 130. These processes may be performed similarly to the example described above.

Subsequently, anchor holes AH penetrating from the resistance layer 130 to the sacrificial layer SA may be formed. Then, a metal material ME may be deposited on the resistance layer 130 and the buffer layer BU. Next, intermetallic compounds may be formed on the metal material ME in contact with the resistance layer 130. Then, the remaining metal material ME may be removed to form a resistance reduction layer 140.

Next, an absorption layer 120 divided by the buffer layer BU may be formed on the anchor holes AH and the resistance reduction layer 140. Subsequently, the sacrificial layer SA may be removed. These processes may be performed similarly to the example described above.

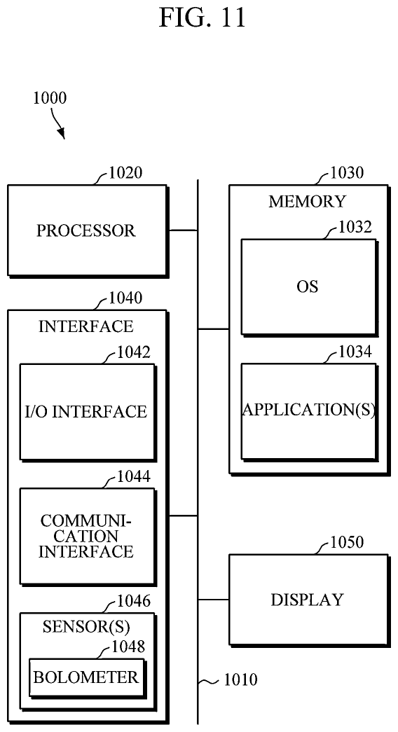

FIG. 11 is a diagram of an electronic device 1000 including a bolometer according to embodiments of the present disclosure. FIG. 11 is for illustration only, and other embodiments of the electronic device 1000 could be used without departing from the scope of this disclosure.

The electronic device 1000 includes a bus 1010, a processor 1020, a memory 1030, an interface 1040, and a display 1050.

The bus 1010 includes a circuit for connecting the components 1020 to 1050 with one another. The bus 1010 functions as a communication system for transferring data between the components 1020 to 1050 or between electronic devices.

The processor 1020 includes one or more of a central processing unit (CPU), a graphics processor unit (GPU), an accelerated processing unit (APU), a many integrated core (MIC), a field-programmable gate array (FPGA), or a digital signal processor (DSP). The processor 1020 is able to perform control of any one or any combination of the other components of the electronic device 1000, and/or perform an operation or data processing relating to communication. The processor 1020 executes one or more programs stored in the memory 1030.

The memory 1030 may include a volatile and/or non-volatile memory. The memory 1030 stores information, such as one or more of commands, data, programs (one or more instructions), and applications 1034, etc., which are related to at least one other component of the electronic device 1000 and for driving and controlling the electronic device 1000. For example, commands and/or data may formulate an operating system (OS) 1032. Information stored in the memory 1030 may be executed by the processor 1020.

The display 1050 includes, for example, a liquid crystal display (LCD), a light emitting diode (LED) display, an organic light emitting diode (OLED) display, a quantum-dot light emitting diode (QLED) display, a microelectromechanical systems (MEMS) display, or an electronic paper display. The display 1050 can also be a depth-aware display, such as a multi-focal display. The display 1050 is able to present, for example, various contents, such as text, images, videos, icons, and symbols.

The interface 2040 includes input/output (I/O) interface 1042, communication interface 1044, and/or one or more sensors 1046. The I/O interface 1042 serves as an interface that can, for example, transfer commands and/or data between a user and/or other external devices and other component(s) of the electronic device 1000. The I/O interface 1042 can also include any one or any combination of a microphone, a keyboard, a mouse, and one or more buttons for touch input.

The sensor(s) 1046 can meter a physical quantity or detect an activation state of the electronic device 1000 and convert metered or detected information into an electrical signal. For example, the sensor(s) 1046 can include one or more cameras or other imaging sensors for capturing images of scenes. In particular, the sensors(s) 1046 may include a bolometer 1048 which corresponds to the microbolometer 100 illustrated in FIG. 1. In addition, the sensor(s) 1046 can include a control circuit for controlling at least one of the sensors included herein. Any of these sensor(s) 1046 can be located within or coupled to the electronic device 1000.

The communication interface 1044, for example, is able to set up communication between the electronic device 1000 and an external electronic device. The communication interface 1044 can be a wired or wireless transceiver or any other component for transmitting and receiving signals.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A microbolometer comprising:
a substrate;
an absorption layer configured to absorb incoming light in a specific wavelength range and comprising an absorption body configured to float from the substrate and electrically isolated by a channel;
a resistance layer provided between the substrate and the absorption body of the absorption layer and having a resistance value that changes based on temperature variations caused by thermal energy absorbed through the absorption layer; and
a resistance reduction layer provided between the absorption layer and the resistance layer to reduce interface resistance and divided by a channel correspond to the channel of the absorption layer.

2. The microbolometer of claim 1, wherein the resistance reduction layer is a high-concentration impurity layer with a doping concentration ranging from 10¹⁸ cm⁻³ to 10²⁰ cm⁻³.

3. The microbolometer of claim 2, wherein the high-concentration impurity layer is formed by depositing donor or acceptor impurities at the doping concentration ranging from 10¹⁸ cm⁻³ to 10²⁰ cm⁻³.

4. The microbolometer of claim 2, wherein the high-concentration impurity layer is formed by ion doping with donor or acceptor impurities at the doping concentration ranging from 10¹⁸ cm⁻³ to 10²⁰ cm⁻³.

5. The microbolometer of claim 1, wherein the resistance reduction layer comprises intermetallic compounds.

6. The microbolometer of claim 1, wherein the channel in the absorption layer and the channel in the resistance reduction layer are filled with a buffer layer.

7. The microbolometer of claim 6, wherein the buffer layer comprises silicon dioxide (SiO) or silicon nitride (SiN).

8. The microbolometer of claim 1, wherein the absorption layer comprises titanium nitride (TiN).

9. The microbolometer of claim 1, wherein the resistance layer comprises amorphous silicon or polycrystalline silicon.

10. The microbolometer of claim 1, wherein the resistance layer and the absorption layer are covered by an insulating film.

11. A method of manufacturing a microbolometer, the method comprising:
operation (a) of forming a row electrode and a column electrode on a substrate, followed by sequentially laminating a sacrificial layer and a resistance layer;
operation (b) of forming anchor holes penetrating from the resistance layer to the sacrificial layer to expose the row electrode and the column electrode, and forming a resistance reduction layer on the resistance layer;
operation (c) of forming an absorption layer on the anchor holes and the resistance reduction layer;
operation (d) of forming an electrically isolating channel penetrating through the absorption layer and the resistance reduction layer; and
operation (e) of removing the sacrificial layer.

12. The method of claim 11, wherein the operation (b) comprises forming the anchor holes penetrating from the resistance reduction layer to the sacrificial layer after forming the resistance reduction layer by depositing donor or acceptor impurities at a doping concentration ranging from 10¹⁸ cm⁻³ to 10²⁰ cm⁻³ onto the resistance layer.

13. The method of claim 11, wherein the operation (b) comprises forming the anchor holes penetrating from the resistance reduction layer to the sacrificial layer after forming the resistance reduction layer by ion doping with donor or acceptor impurities at a doping concentration ranging from 10¹⁸ cm⁻³ to 10²⁰ cm⁻³ on the resistance layer.

14. The method of claim 11, wherein the operation (b) comprises depositing a metal material on the resistance layer and the anchor holes after forming the anchor holes penetrating from the resistance layer to the sacrificial layer, and forming the resistance reduction layer by removing a remaining metal material after forming intermetallic compounds on the metal material in contact with the resistance layer.

15. The method of claim 11, wherein the operation (a) further comprises forming an insulating film between the sacrificial layer and the resistance layer.

16. A method of manufacturing a microbolometer, the method comprising:
operation (a) of forming a row electrode and a column electrode on a substrate, followed by sequentially laminating a sacrificial layer and a resistance layer;
operation (b) of patterning a buffer layer on the resistance layer;
operation (c) of forming anchor holes penetrating from the resistance layer to the sacrificial layer to expose the row electrode and the column electrode, and forming a resistance reduction layer on the resistance layer such that the buffer layer is exposed to a set height;
operation (d) of forming an absorption layer, which is divided by the buffer layer, on the anchor holes and the resistance reduction layer; and
operation (e) of removing the sacrificial layer.

17. The method of claim 16, wherein the operation (c) comprises forming the anchor holes penetrating from the resistance reduction layer to the sacrificial layer after forming the resistance reduction layer by depositing donor or acceptor impurities at a doping concentration ranging from 10¹⁸ cm⁻³ to 10²⁰ cm⁻³ onto the resistance layer such that the buffer layer is exposed to the set height.

18. The method of claim 16, wherein the operation (c) comprises forming the anchor holes penetrating from the resistance reduction layer to the sacrificial layer after forming the resistance reduction layer by ion doping with donor or acceptor impurities at a doping concentration ranging from 10¹⁸ cm⁻³ to 10²⁰ cm⁻³ on the resistance layer such that the buffer layer is exposed to the set height.

19. The method of claim 16, wherein the operation (c) comprises depositing a metal material on the resistance layer, the buffer layer, and the anchor holes after forming the anchor holes penetrating from the resistance layer to the sacrificial layer, and forming the resistance reduction layer by removing a remaining metal material after forming intermetallic compounds on the metal material in contact with the resistance layer.

20. The method of claim 16, wherein the operation (a) further comprises forming an insulating film between the sacrificial layer and the resistance layer.
